(19) United States
(12) Patent Application Publication
(10) Pub. No.: US 2025/0216635 A1
(43) Pub. Date: Jul. 3, 2025

(54) Optical Chip-to-Chip Interconnect and Method of Integration

(71) Applicant: Hyperlume Inc., Ottawa (CA)

(72) Inventor: Mohsen Asad, Ottawa (CA)

(73) Assignee: Hyperlume Inc., Ottawa (CA)

(21) Appl. No.: 19/064,694

(22) Filed: Feb. 27, 2025

Related U.S. Application Data
(63) Continuation of application No. PCT/IB2024/056998, filed on Jul. 18, 2024.
(60) Provisional application No. 63/514,210, filed on Jul. 18, 2023.

(51) Int. Cl. G02B 6/42; H01L 25/16; H01L 25/18

(52) U.S. Cl. CPC G02B 6/4295; G02B 6/4214; G02B 6/4239; H01L 25/167; H01L 25/18

(57) ABSTRACT

In order to enable applications such as artificial intelligence (AI) and machine learning in a large scale, a large amount of information needs to be processed very fast. To improve the speed of the computation, not only faster graphical and central processors are required, but also the communication between processors and high bandwidth memories should be fast enough to reduce the latency. Optical interconnect can be a replacement for copper interconnect which is providing larger bandwidth and lower latency. As an efficient light source, micro-LEDs can be used as light source for chip-to-chip optical interconnect. Using a massively parallel memory-processor interconnect using low-power micro-LED, the computation speed will increase dramatically, and less amount of energy will be wasted through copper self-heating.

### CROSS-REFERENCE TO RELATED APPLICATIONS

This utility patent application claims priority from U.S. provisional patent application Ser. No. 63/514,210, filed Jul. 18, 2023, titled “Optical Chip-to-Chip Interconnect and Method of Integration”, and naming inventor Mohsen Asad.

### COPYRIGHT NOTICE

A portion of the disclosure of this patent document contains material that is subject to copyright protection. The copyright owner has no objection to the facsimile reproduction by anyone of the patent document or the patent disclosure, as it appears in the Patent and Trademark Office patent file or records, but otherwise reserves all copyright rights whatsoever. Copyright 2024, Hyperlume Inc.

### BACKGROUND

### Field of Technology

This relates to high speed computing, and more particularly to optical interconnect chiplets.

### Background

In order to process big data faster, more powerful processing units are required. Traditionally, the processing units were made faster year by year with increasing the number of transistors in a chip by making them smaller. However, due to the semiconductor fabrication limits, it is not easy anymore to increase the speed by shrinking the transistor size. To address this issue, larger numbers of processing units are packaged together which increases the processors' density.

At a certain level of processing speed, the interconnect between the chips is not sufficient to exchange big data between them fast and without delay and causing latency.

In addition, new applications require access to larger memories as a location where information and orders are stored. High bandwidth memories were made to enable large data transfer input/output ports, however, when the space between memories processing units were far, a latency (delay in time) in sending and receiving information was created which prevents system sync.

As a solution, optical interconnect was considered for replacement of copper wire. Optical communication based on fiber optics has been used for a long time to transmit information between cities and datacenters. However, laser diodes are still a bottleneck for system development. They are not efficient enough and generate unwanted heat. In addition, the heat generated accelerates the device aging process and creates reliability issues. Also, lasers are expensive light sources with high sensitivity to back reflection. All these disadvantages makes laser diodes not scalable interconnects between chips.

### BRIEF SUMMARY

In order to enable applications such as artificial intelligence (AI) and machine learning on a large scale, a large amount of information needs to be processed very fast. In addition, most of the heavy calculations happen inside data centers. To improve the speed of the computation, not only are faster graphical and central processors required, but also the communication between processors and high bandwidth memories should be fast enough to reduce the latency. Due to its intrinsic material properties, copper interconnects are not be able to provide the bandwidth required for high performance computing. In addition, a portion of the electrical signal and data transmitted through copper interconnects is wasted in form of heat. Optical interconnects can be a replacement for copper interconnects and provide larger bandwidth and lower latency. Laser diodes as a light source still suffer from low efficiency, poor reliability, and a complex packaging process which prevents them to be used for short-reach communication. Micro-LEDs are a promising low-power light source that can be used for optical interconnect. In comparison to laser diodes, they are very cheap and not sensitive to heat. However, techniques are required to integrate them on optical substrates and couple the emitted light into optical waveguides. As an efficient light source, micro-LEDs can be used as light source for chip-to-chip optical interconnects. In addition, an extra layer of serialize/deserialize IP is not required for this optical link which makes it more power efficient. Using a massively parallel memory-processor interconnect using low-power micro-LEDs, computation speed will increase dramatically, and less energy will be wasted compared to copper self-heating. Considering the scales required for massive computation and communication, a sustainable technology such as micro-LED interconnect will help reduce global warming and CO₂ generation.

### BRIEF DESCRIPTION OF THE DRAWINGS

For a better understanding of the various examples described herein and to show more clearly how they may be carried into effect, reference will now be made, by way of example only, to the accompanying drawings in which:

FIG. 1 depicts an optical substrate with optical waveguide and dielectrics on it.

FIG. 2 depicts the optical substrate with multilayer optical waveguide and dielectrics on it.

FIG. 3 depicts the optical substrate after patterning and removing some areas.

FIG. 4 depicts the optical substrates after assembling mirrors inside the trenches.

FIG. 5 depicts the optical substrate after assembling a mirror using adhesive inside the trenches.

FIG. 6 depicts the optical substrate of FIG. 5 with a light path from a light source to a detector.

FIG. 7 depicts an optical chiplet which is combination of an optical substrate and active optical devices substrates with an LED and detector on it.

FIG. 8 depicts an optical chiplet which the light source is on an optical device substrate and detector is made in an optical substrate.

FIG. 9 depicts an optical chiplet with optical light path from both sides. Optical information is transferred from both sides and detectors are assembled on top of waveguide.

FIG. 10 depicts an optical chiplet with optical light path from both sides. Detectors are made in plane with optical waveguide.

FIG. 11 depicts an optical chiplet which is made with a vertical LED and detector on a device substrate and a waveguide on an optical substrate.

FIG. 12 depicts an optical chiplet with optics assembled on top of an LED and reflectors are created on the sidewall of the LED.

FIG. 13 depicts an optical chiplet where both LED and detector have guiding optics on top of them.

FIG. 14 depicts an optical chiplet with a guiding optics installed on top of an LED and detector in wafer-level packaging.

FIG. 15 depicts an optical chiplet where double side data traffic is made by LEDs and in-plane detectors and sides of LEDs are covered with an optical material.

FIG. 16 depicts an optical chiplet with a laser diode used a light source and a detector is made in-plane with waveguide.

FIG. 17 depicts an optical chiplet where laser diode is assembled on the optical substrate with optical waveguide.

FIG. 18 depicts an optical chiplet where a laser diode with an external cavity is assembled on the optical substrate.

FIG. 19 depicts an optical chiplet with an LED integrated with an optical element.

FIG. 20 depicts an optical chiplet with multiple light sources, multiple photodetectors, and multi-layer waveguides.

FIG. 21 depicts an optical chiplet with multiple light sources and multiple photodetectors which are made in-plane with waveguide and multilayer optical waveguides.

FIG. 22 depicts an optical chiplet with inverted waveguide with waveguides and mirrors fabricated on an optical substrate with hard stops.

FIG. 23 depicts an optical chiplet with inverted waveguide installed on the optical device substrate.

FIG. 24 depicts a bare optical substrate with specific crystal orientation.

FIG. 25 depicts an optical substrate after removing a patterned area.

FIG. 26 depicts an optical substrate after forming an optical waveguide on it.

FIG. 27 depicts an optical substrate after forming multi-layer optical waveguide on it.

FIG. 28 depicts an optical chiplet with an inverted optical waveguide assembly.

FIG. 29 depicts an optical chiplet with multiple light sources, multiple photodetectors, and an inverted multilayer waveguide assembly.

FIG. 30 depicts an optical chiplet with bonding pads at the sides.

FIG. 31 depicts an optical chiplet connected to ASICs using bonding pads on the die to die adaptor IP.

FIG. 32 depicts an optical chiplet connected to ASICs on the backside using bonding pads and through substrate vias (TSVs).

FIG. 33 depicts an optical chiplet connected to ASICs using TSVs interfaced with die to die adaptor IPs.

FIG. 34 depicts an optical chiplet with optical source, optics on topside, and connected to ASICs.

FIG. 35 depicts an optical chiplet with optical source and optic on topside and ASICs are connected to it on the backside using TSVs.

FIG. 36 depicts an optical chiplet that an optical waveguide is made on topside and optical source and optic are assembled on topside. ASICs are connected to the die's topside using bonding pads.

FIG. 37 depicts an optical chiplet that an optical waveguide is made on topside and optical source and optic are assembled on topside. ASICs are connected to the die's backside using TSVs.

FIG. 38 depicts an optical structure to couple photons from a light source to an external waveguide.

FIG. 39 depicts an optical structure to separate a light source structure from another optical substrate.

FIG. 40 depicts an optical structure to couple light from an external light source or fiber optic to an optical waveguide on another optical substrate.

### DETAILED DESCRIPTION, INCLUDING THE PREFERRED EMBODIMENT

Various exemplary embodiments of the present invention will now be described in detail with reference to the drawings. It should be noted that the relative arrangement of the components and steps, the numerical expressions, and numerical values set forth in these embodiments do not limit the scope unless it is specifically stated otherwise.

The following description of at least one exemplary embodiment is merely illustrative in nature and is in no way intended to be limiting, including in applications or uses.

Techniques, methods, and apparatus as known by one of ordinary skill in the relevant art may not be discussed in detail but are intended to be part of the specification where appropriate.

In all the examples illustrated and discussed herein, any specific values should be interpreted to be illustrative only and non-limiting. Thus, other examples of the exemplary embodiments could have different values.

Notice that similar reference numerals and letters refer to similar items in the following figures, and thus once an item is defined in one figure, it is possible that it need not be further discussed for following figures.

Below, the embodiments and examples will be described with reference to the accompany figures.

FIG. 1 depicts an optical substrate (100) which may be a silicon, glass, or any other substrate which can be used to run fabrication processes on it. Layer (101) is an optical waveguide to transmit photons. Layer (101) may be made from any organic materials such as polymer or be made from any inorganic materials such as silicon, SiN or any other dielectrics. Layers (102) and (103) are dielectric with a different dielectric constant than optical waveguide (101) and act like a clad to maintain the photons inside the waveguide.

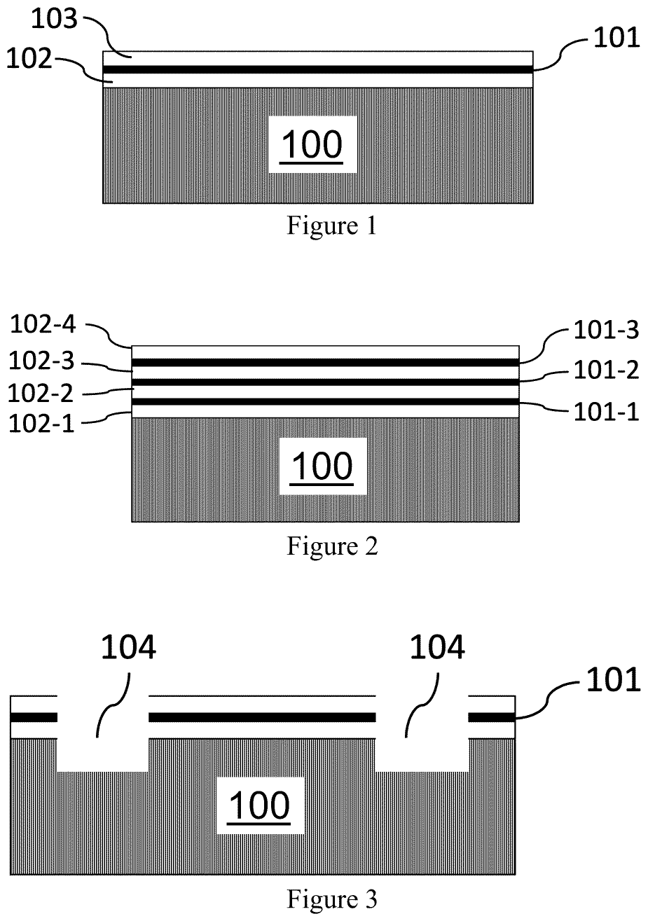

FIG. 2 depicts an optical substrate (100) with multilayer optical waveguides (101-1), (101-2), (101-3) on it. Multilayer waveguides are not limited to 3 layers and can be any number of layers. Each layer can be used individually to transmit optical information from different optical sources. Layers (102-1), (102-2), (102-3), (102-4) are cladding layers with a different dielectric constant from the optical waveguides to keep the photons inside the waveguides. The cladding layers may be made with different dielectric constants and with different thicknesses to stop the optical interference between optical waveguides. In addition, the number of cladding layers between optical waveguide layers is not limited to one layer and each can be made in a multi cladding structures.

FIG. 3 depicts the optical substrate after patterning and etching to create trenches in regions (104). Each trench (104) is deep enough to get access to the optical waveguide(s) from the side and provides enough space to assemble an optical element within. Each trench (104) can be created by conventional semiconductor processes such as lithography, etching, etc. Each trench (104) can be made to access the waveguide(s) from each side or may be created to access only one side. As will be later discussed, multiple trenches may be created with the optical waveguide(s) between the trenches, a single trench may be created with the optical waveguide(s) above the optical substrate adjacent to the trench, a single trench with angled sidewalls may be created with the optical waveguide(s) between the angled sidewalls, or a single trench with one angled sidewall may be created with the side opposite the angled sidewall removed to lead off the optical substrate.

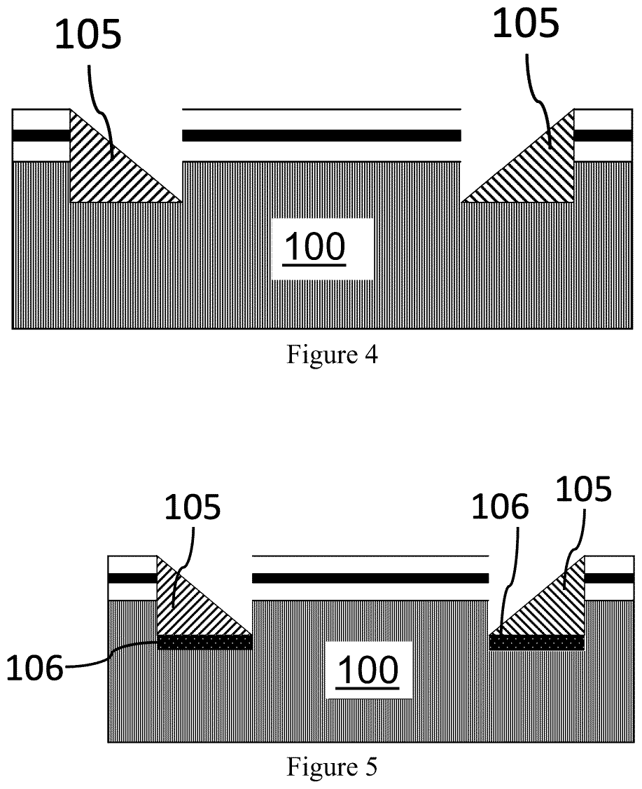

FIG. 4 depicts the assembly of the optical mirrors (105) into each trench. The optical mirror (105) may be made from any substrate such as glass or silicon and may have an optical coating on it from different dielectric or metal layers. The optical mirror may be a wide band mirror or it may have a filter on it to filter part of the optical spectrum.

FIG. 5 depicts assembly of the optical mirror (105) into each trench using a bonding agent (106). The bonding agent (106) may be made from thermal or heat curing polymers, metals or any other material that may provide mechanical rigidity. The optical agent (105) may be placed (dispensed) inside a trench before optical mirror (105) assembly or may be coated on bottom side of the optical mirror (105). The sequence of the process may be different from what is mentioned here.

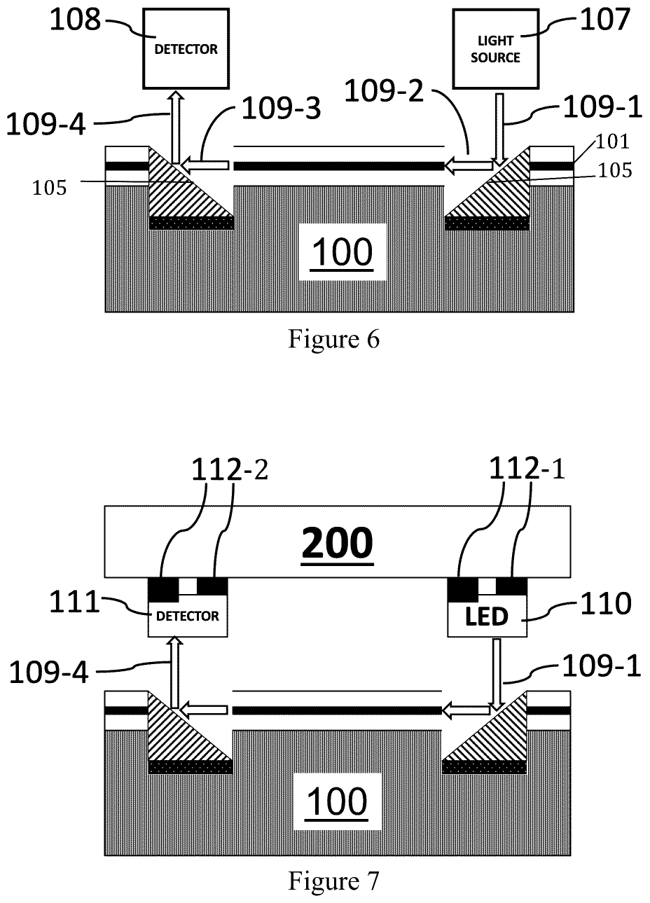

FIG. 6 depicts photons (109-1) emitted from light source (107) towards mirror (105). The reflected photons (109-2) are coupled into the optical waveguide (101). The extracted photonic (109-3) from the waveguide are emitted toward another optical mirror (105). The guided photons (109-4) will reach the detector (108) to be converted to electrical signal. The detector (108) can be made from any materials. The angled optical mirrors (105) can reflect all the photons only into one side, or the photons can partially be emitted in different sides.

FIG. 7 depicts an optical system where the optical waveguide received light from LED (110) light source and directs the light to detector (111), which are assembled on an active substrate (200). The active substrate (200) may contain driving circuits (112-1) for modulating the LED and readout circuits (112-2) to read the values of the detector. The optical substrate (100) may have passive or active optical component.

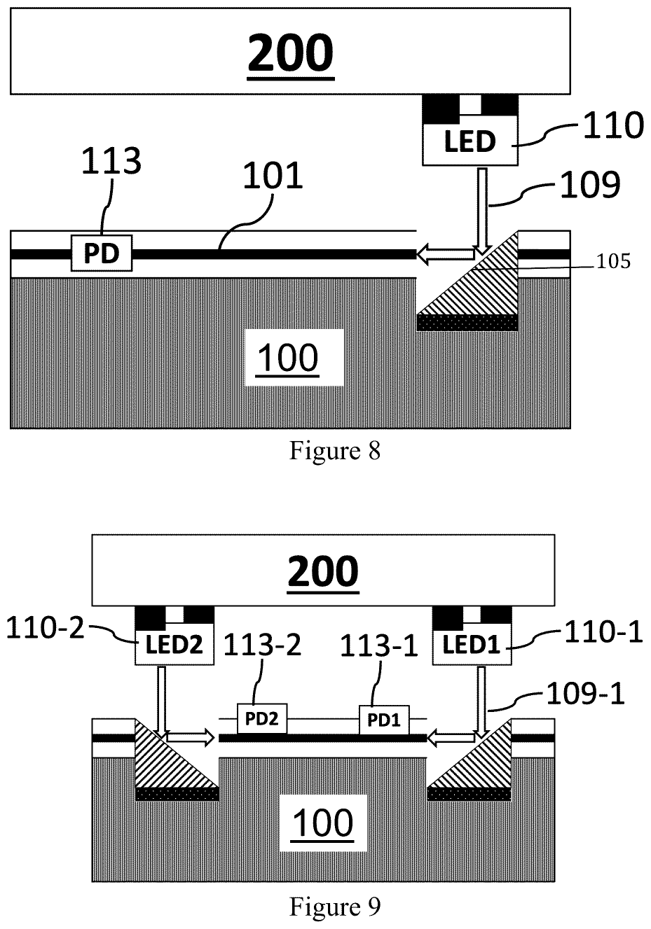

FIG. 8 depicts an optical system with photodetector (PD) (113) fabricated on optical substrate (100). The PD may be fabricated in the same plane as optical waveguide (101) from the same material or from other kind of materials. Photons (109) emitted from the LED (110) are directed toward optical waveguide (101) using an optical mirror (105-1). The electronics to drive the PD may be fabricated on the optical substrate (100) or may be assembled on the substrate.

FIG. 9 depicts an optical system with double optical pathways. The optical system may be developed in a way that information from each side can be transmitted using LEDs (110-1), (110-2) and can be detected on each end using PDs (113-1), (113-2). The PDs may be fabricated over the optical waveguide and the light coupling may be through different technologies such as evanescent modes or direct coupling. The PD readout circuit may be fabricated on the same optical substrate (100). LED drivers may be fabricated on the electronic substrate (200).

FIG. 10 depicts an optical system where PDs (113-3), (113-4) are fabricated on the same plane as waveguides. The photons generated from LEDs (110-1), (110-2) are coupled to the optical waveguide(s) using optical mirrors and may be detected at the other side of the optical substrate (100) using a PD. PDs (113-3), (113-4) may be both on the same optical waveguide or may be made on different optical waveguides. The emission wavelength of the LEDs (110-1) and (110-2) may be different or they may emit the same optical spectrum.

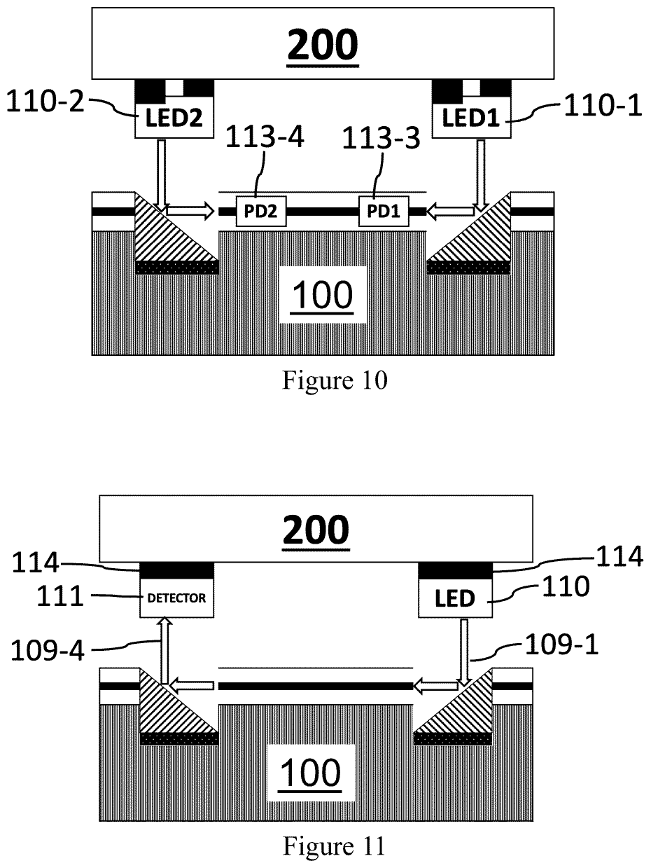

FIG. 11 depicts an optical system where a vertical LED (110) and vertical detector (111) are used to send and receive information. LED (110) and detector (111) are connected to the electronic substrate (200) using bonding agents (114) which may be fabricated from different materials.

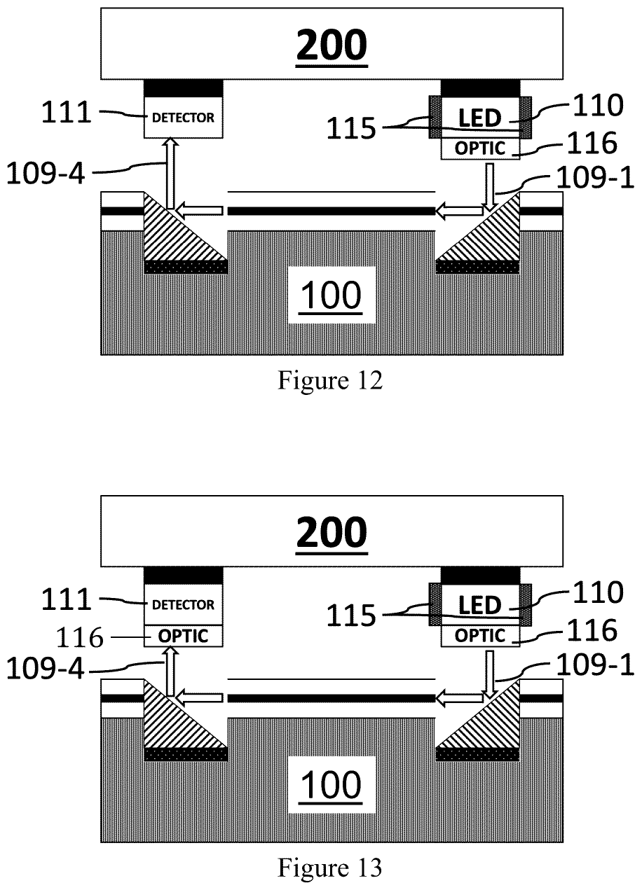

FIG. 12 depicts an optical system where an optics (116) is assembled on LED (110) to modify the optical emission such as collimating or focusing or etc. Sidewalls of the LED can be also can be functional using an external material (115) that may be fabricated using coating or any other fabrication techniques.

FIG. 13 depicts an optical system where both LED (110) and detector (111) may be equipped with an optical element (116). The optical element may be made by assembling and external optical component or by coating optical layers on LED or detector. The optical design on top of LED and PD may be different for various optical properties.

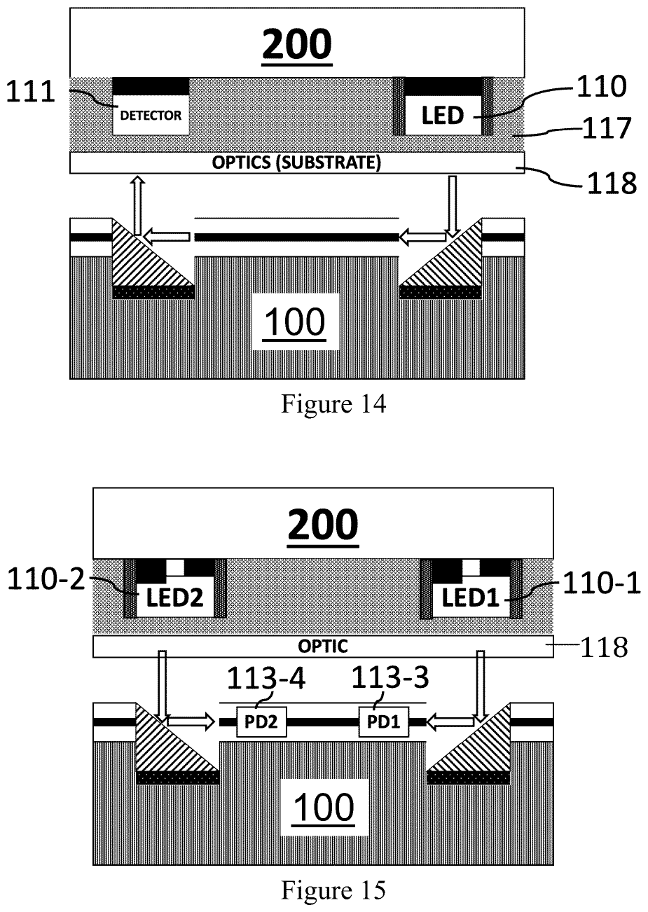

FIG. 14 depicts an optical system with a wafer-level optical assembly on the LED and detector. In this structure the optic (118) may be assembled on LEDs and detectors using a bonding agent (117) which may be optical epoxy, glue, or any other form of materials.

FIG. 15 depicts an optical system with LEDs (110-1), (110-2) on electronic substrate (200) and PDs (113-3), (113-4) made on the optical substrate (100). An optical element (118) may be integrated on LEDs in a wafer-level or die-level assembly using a bonding agent.

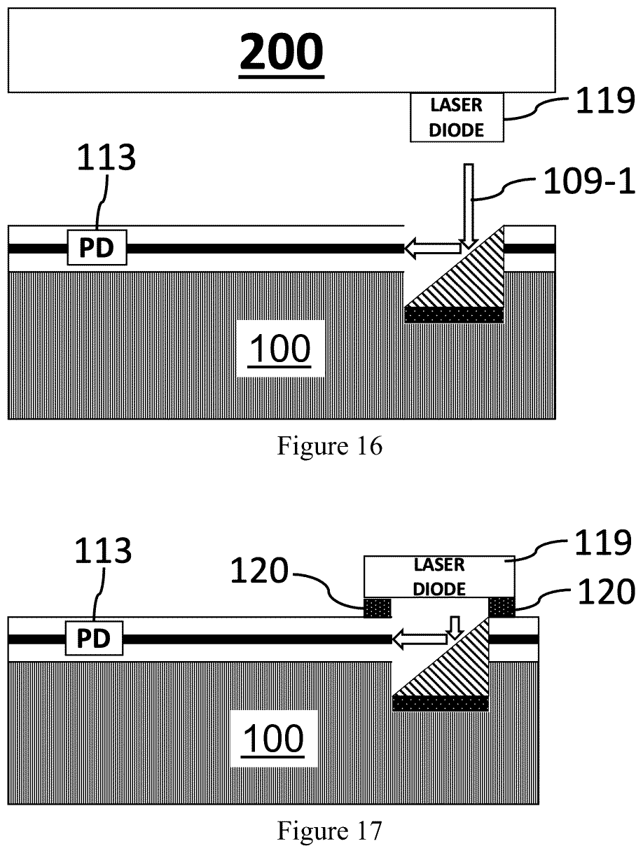

FIG. 16 depicts an optical system with a laser diode (119) as a light source. The laser diode (119) may be assembled or epitaxially grown on the electronic substrate (200). An electronic driver may be made on the electronic substrate (200). The laser diode (119) can be from different technologies such surface emitting or edge emitting devices.

FIG. 17 depicts an optical system with laser diode (119) integrated on the optical substrate (200). The laser diode (119) may be installed on the optical substrate using a connection (12) such as a bonding agent or a hard stop. Emitted photons from the laser diode (119) may be guided toward the optical waveguide using an optical mirror and may be detected at the other side using a in-plane PD (113).

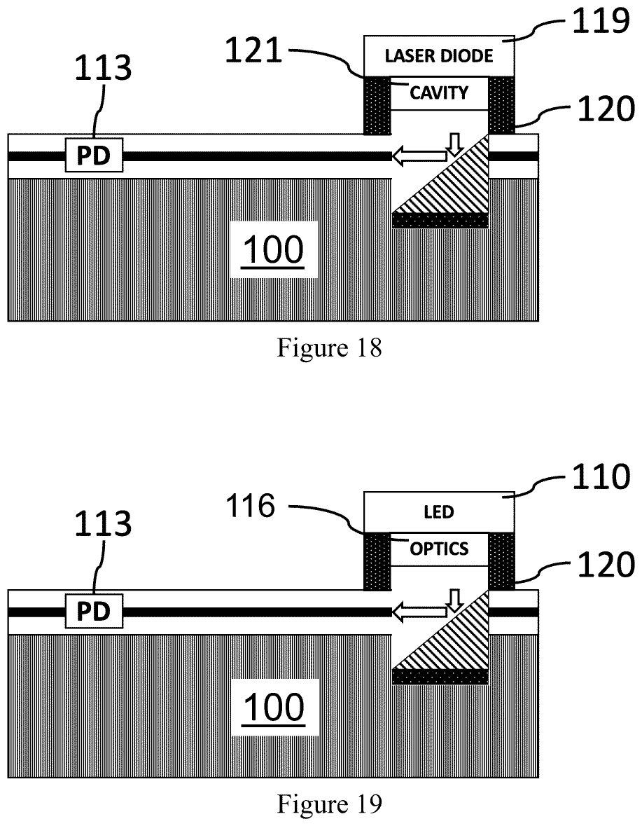

FIG. 18 depicts an optical system with a laser diode (119) integrated on the optical substrate (100). An external cavity (121) may be installed on the laser diode to enhance the optical power of the laser diode or to modify the emission optical spectrum. The connection (120) may be a bonding agent or a hard stop. The sequence of integrating the cavity and laser diode on the optical substrate may vary.

FIG. 19 depicts an optical system with a LED (110) as a light source integrated on the optical substrate (100). An optical element (116) may be installed on LED (110) to modify the optical properties. PD (113) may be fabricated or assembled on the optical substrate (100) to detect the photons. The LED (110) integration may be perform using any technique that may transfer the LED on to the optical substrate (100).

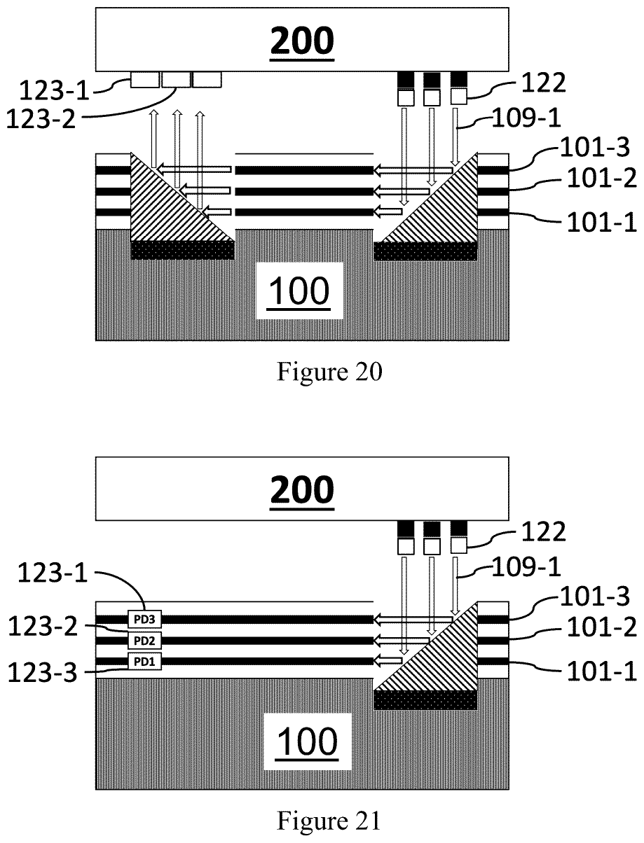

FIG. 20 depicts an optical system that may have multi-layer optical waveguides (101-1), (101-2), (101-3). The waveguide may be fabricated in one layer or multilayer without limitation on the number of layers. One or more light sources (122) may be installed (assembled) on the electrical substrate (200) such that each light source (122) emits photons to be coupled to individual waveguides (101-1), (101-2), (101-3). Light sources (122) may be at a 1:1 ratio with the waveguides, or at a 1:many ratio such that there are more waveguides than light sources. Different PDs (123-1), (123-2) may be used to detect the photons and convert optical information to electrical information. The number of the optical light sources (122) and PDs (123) may be identical, or they may be in different order.

FIG. 21 depicts an optical system with PDs (123-1), (123-2), (123-3) in plane with waveguides (101-1), (101-2), (101-3). The light sources (122), which may be LEDs or laser diodes, are integrated on electrical substrate (200). The optical mirror reflects the photons such as (109-1) that are emitted from the light sources toward the waveguides (123-1), (123-2), (123-3) which are guiding the photons towards other side of the optical substrate (100) and other optical elements such as PDs or other active or passive optical elements.

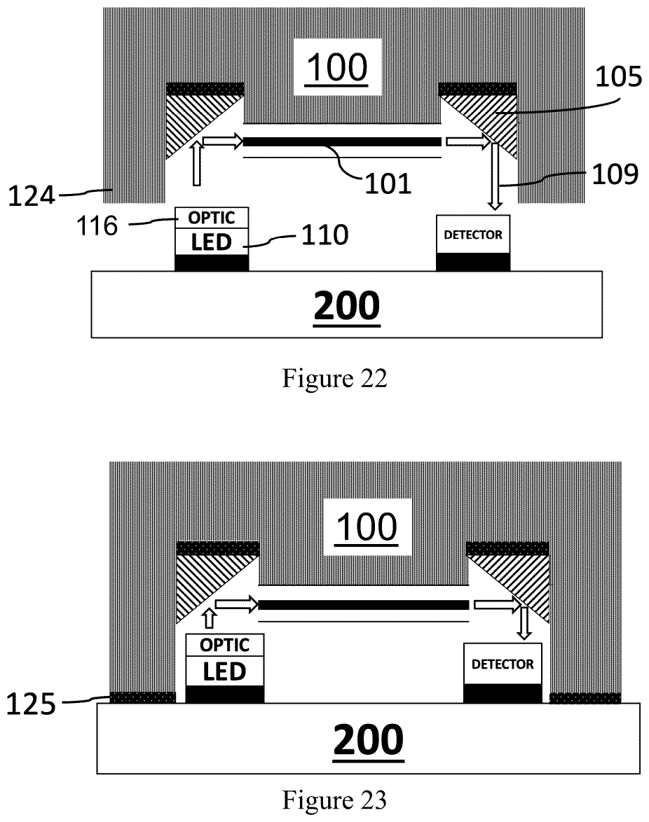

FIG. 22 depicts an optical system where optical substrate (100) with waveguide (101) can be installed on an electronic substrate (200). The elements such as LED (110), optics (116), detector and driving circuit are installed on the electronic substrate (200). The optical substrate (100) may have hard-stop (124) which may define the space between the optical substrate (100) and the electrical substrate (200).

FIG. 23 depicts an optical system after integrating the optical substrate (100) on the electrical substrate (200) using a bonding agent (125) which may be any dielectric, metal, epoxy, or any other material. The hard stop geometry may be different from this embodiment and may be a step-like structure. The hard stop may contact the electrical chip directly after assembly.

FIG. 24 depicts an optical substrate (300) which may be in crystal orientation (100). The crystal orientation of the optical substrate may be chosen in a way that chemical processing can etch one specific crystal orientation more than others.

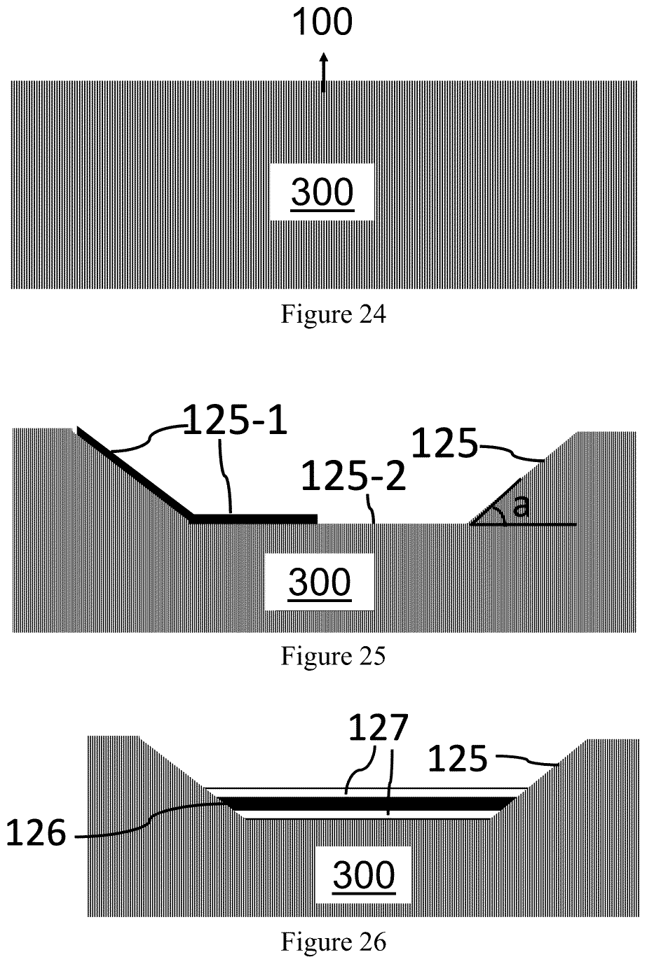

FIG. 25 depicts an optical substrate (300) after patterning and removing (etching) a section of it. The angle (a) between the sidewall (125) and base of the substrate (125-2), after etching, is made due to various etch speed of different crystal orientation. The sidewall (125) may be coated with a reflective material (125-1) which may be a broadband absorber or may filter part of the spectrum. As shown in the FIG. 25, the reflective material (125-1) can coat all sidewalls (125) and base of the substrate (125-2).

FIG. 26 depicts an optical substrate (300) with a waveguide (126) made inside of it. The optical waveguide material may be silicon, dielectric, polymer, or any other material that can guide photons. The optical waveguide (126) may be sandwiched between dielectric layers (127). Dielectric layers (127) may be fabricated using oxidation, coating, or any other type of fabrication process. The facet of the waveguide (127) may be attached to the sidewall (125) of the optical substrate (300).

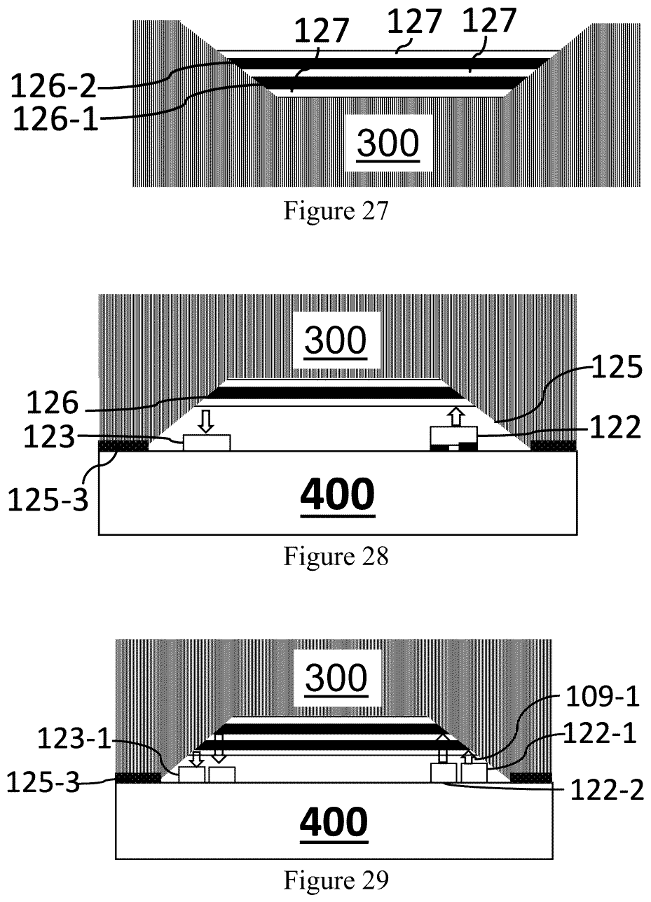

FIG. 27 depicts an optical substrate (300) with multiple optical waveguides (126-1), (126-2). The number of optical waveguides may vary depending on the structure and bandwidth required. Dielectric layers (127) may separate the optical waveguides (126-1), (126-2). The dielectric properties of each layer between optical waveguides may be the same or different to provide optical insulation or interaction.

FIG. 28 depicts an optical substrate (300) with waveguide (126) after integration on a electrical substrate (400). The edge of the optical substrate may act like a hard-stop to control the spacing between the optical substrate (300) and electrical substrate (400). Light source (122) and PD (123) may be integrated on the electrical substrate (400) using solder, epoxy, or any other mean of integration. Photons emitted from the light source (LS) may be coupled to the waveguide (126) after angled reflection from the optical substrate angled sidewall (125). The optical properties of the optical waveguide may be different at the edge and at the center of the waveguide. A bonding agent (125-3) may be used to integrate the optical substrate (300) to the electronic substrate (400). The angled sidewall (125) of the optical substrate may be coated with a reflective material.

FIG. 29 depicts an optical system with multiple light sources (122-1), (122-2), and multiple PDs (123-1) and multiple optical waveguides. The emitted photons (109-1) from the LS1 (122-1) will be coupled to optical waveguide and after another reflection may be guided to PD1 (123-1). The number of light sources, PDs, or waveguides may not be limited to what depicted here and may change based on system requirements.

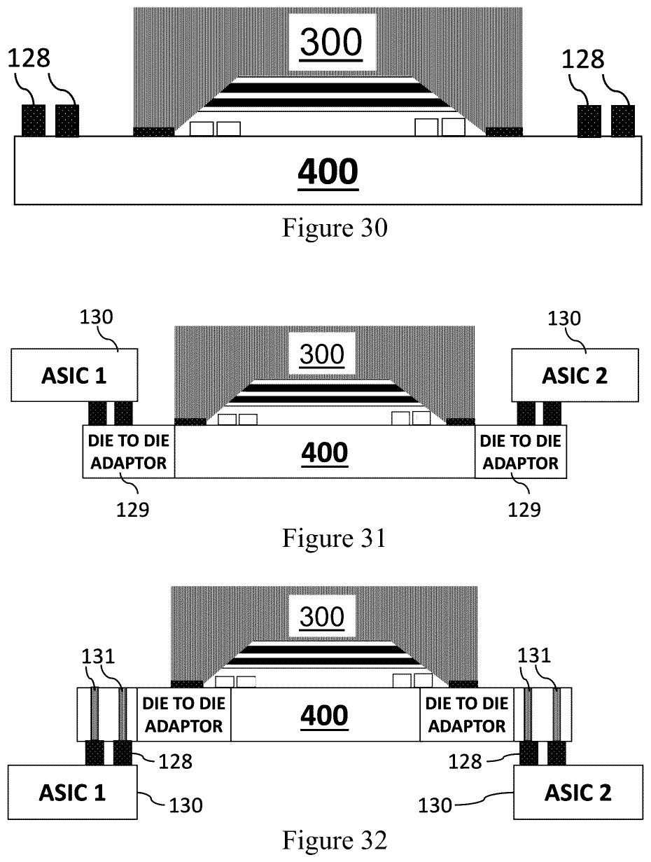

FIG. 30 depicts an optical system with bonding pads (128) created close to the edge of the electrical substrate (400). The bonding pads (128) may be used to connect other integrated circuits (ICs) through the optical and electrical link on this optical system. The electrical signal may be transferred from a third-party IC to this optical system and be converted to optical signal at the light sources. The optical signal after traveling through the waveguide may be converted to electrical signal at the PDs and transferred to another IC at the other side of the electrical substrate using bonding pads.

FIG. 31 depicts an optical interconnect that connects two application specific integrated circuits (ASICs) (130) together. In this structure, ASIC1 and ASIC2 are connected to the optical interconnect using bonding pads. If the communication protocol of the ASICs is different from the communication protocol of the optical interconnect, a die-to-die adaptor (129) may be implemented in the electrical substrate (400). The die-to-die adaptor may be designed in a way to make the optical interconnect agnostic to any protocol. The number and pitch of the bonding pads may change according to the bandwidth requirement.

FIG. 32 depicts an optical interconnect that connects two ASICs (130). ASICs are connected to the electrical substrate (400) from the backside using through substrate vias (TSVs) (131). In this structure a die-to-die adaptor (129) is implemented in the electronic substrate (400) to communicate with the ASICs (130). The optical substrate (300) still may have the optical waveguides. ASICs (130) may be embedded in another material, or another substrate, and they may be flat or not flat. The optical interconnect may be used to make an array of the ASICs (130) and increase the bandwidth or reduce the communication latency or power consumption.

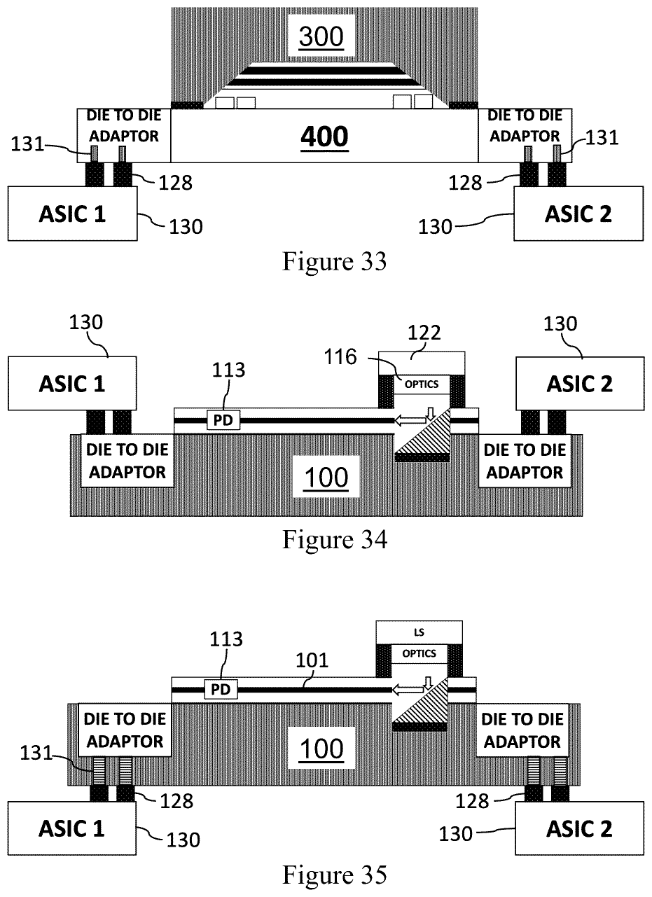

FIG. 33 depicts an optical interconnect that is connected to two ASICs (130) using TSVs (131). The TSVs (131) may go up to the surface of the electrical substrate (400) or may just be connected to an internal layer. In addition, the backside of the electrical substrate (400) may be used to transfer driving power between ASICs (130). TSVs (131) may be connected to the ASICs (130) using bonding pads (128).

FIG. 34 depicts an optical interconnect with die-to-die adaptors embedded into the optical substrate (100). The optical interconnect may be connected to ASICs (130) and a light source (122) and optics (116) may be used to generate optical signals. The photons may be coupled to the waveguide using an optical mirror and may be detected at the other side of the interconnect using PD (113). The ASICs (130) are connected to the die-to-die adaptor using bonding pads. The die-to-die adaptors may be integrated to the optical substrate (100) with processes such as die to die or die to wafer bonding. The die-to-die adaptors may be made in optical substrate (100) using the same co-CMOS-Photonic process (such as co-package optic process). The light source (122) driver may be fabricated in the optical substrate and may be connected using electrical contact.

FIG. 35 depicts an optical interconnect that connects ASICs (130) using TSVs (131) from the interconnect's backside. The interconnect is made using an optical substrate (100) and embedding die-to-die adaptors in the substrate. The die-to-die adaptors may be assembled, may be integrated, or may be fabricated on the optical substrate (100). The adaptor is connected to the ASICs (130) using TSVs. The LS and PD (113) are driven using circuits that may be externally assembled on the optical substrate or may be fabricated on the optical substrate (100).

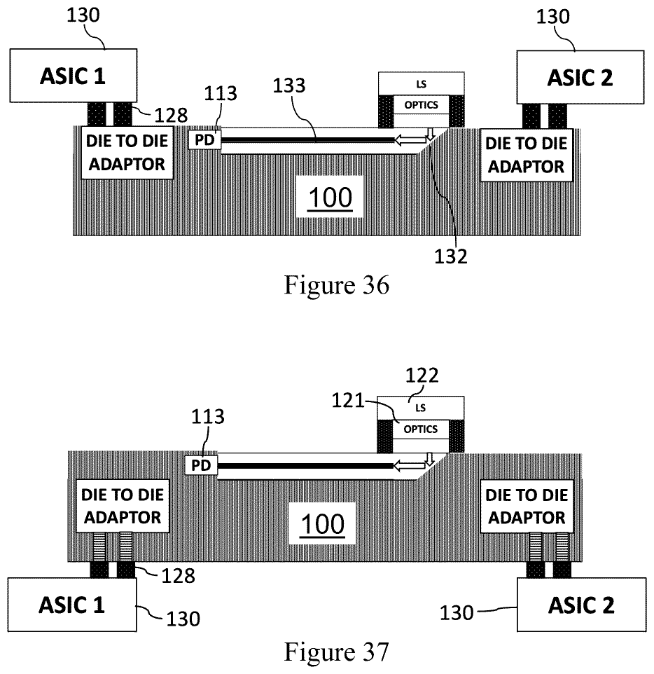

FIG. 36 depicts an optical interconnect where the light source is integrated on the optical substrate (100) and part of the substrate is processed to create an optical mirror (132) and optical waveguide (133). Die-to-die adaptors may be fabricated or integrated into the optical substrate (100). Bonding pads (128) connect ASICs (130) to the optical substrate (100). A PD (113) that may be fabricated or integrated at the other side of the waveguide can detect photons.

FIG. 37 depicts an optical interconnect that may connect ASICs (130) using TSVs on its backside. Optical substrate (100) is processed to have a mirror-shaped structure on it. A waveguide that may be fabricated using other materials than the optical substrate guides the light from the light source (122) towards PD (113) and other side of the chip. Die to die adaptors may be embedded into the optical substrate.

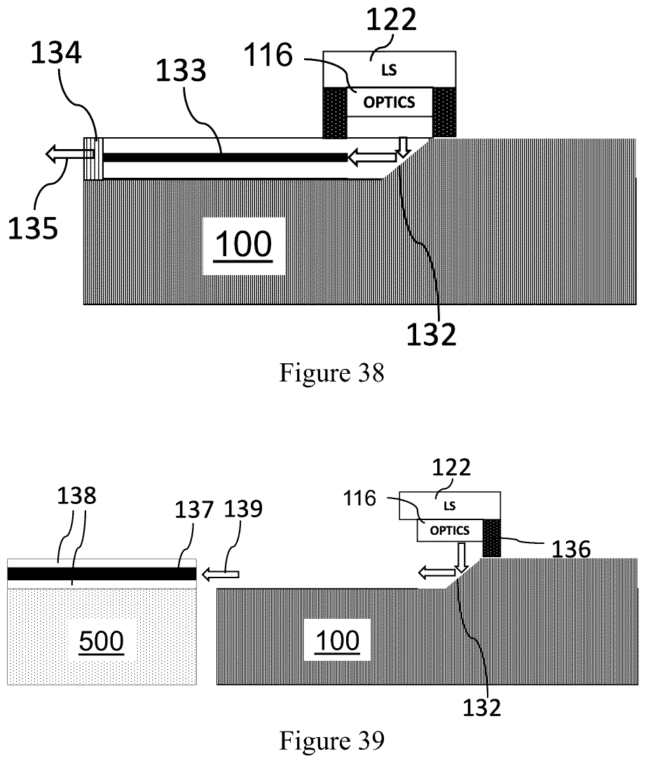

FIG. 38 depicts an optical structure to couple photons from a light source (122) to an external waveguide (133). The waveguide (133) facet may be covered with a reflective material (134) which reflects photons backward. The waveguide (133) and reflective element (134) may act like an external cavity for the light source and may be used to filter the light, or enhance the optical power. The light source (122) may have an optics (121) in front of it and that may be used for optical insulation, collimation, or any other optical modification. The optics (116) may consist of several optical components. Photons (135) emitted from the cavity may be different from the photons generated from in the light source in terms of power, frequency, or any other optical property, or they may be the same. The optical reflective (134) may not be used in some structure and the whole structure may be used to guide the light from a surface emitting light source to an edge emitting device. The reflective sidewall may be coated with several layers of dielectric or a reflective metallic layer to act as an optical mirror (132).

FIG. 39 depicts an optical structure to separate the light source structure from another optical substrate (500). The light source may be driven using bonding pad (136) or any other kind of electrical contact. After reflection at the reflective sidewall (132) surface, emitted photons (139) may be guided to another optical waveguide (137) on another optical substrate (500). The optical waveguide (137) may be clad with dielectric layer (138) on top and bottom with different thickness and different dielectric constants. The two substrate (100) and (500) may be aligned to maximize light coupling from light source (122) to optical waveguide (137).

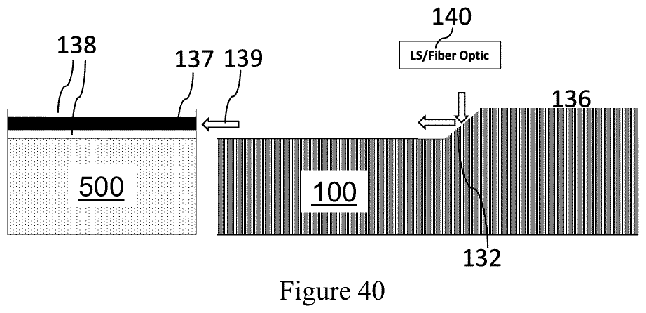

FIG. 40 depicts an optical structure to couple light from an external light source or fiber optic (140) to an optical waveguide (137) on another optical substrate (500). In this structure, the light source or the fiber optic may be pre-assembled on the optical substrate (100). By aligning the optical substrate (100) with optical substrate (500) the light can be coupled to the waveguide (137).

It is to be understood that the above description is intended to be illustrative, and not restrictive. Many other embodiments will be apparent to those of skill in the art upon reviewing the above description. The scope should, therefore, be determined with reference to the appended claims, along with the full scope of equivalents to which such claims are entitled.

1. An optical interconnect comprising:
an optical substrate;
one or more trenches in the optical substrate;
one or more optical waveguides;
one or more LED light sources;
one or more driving circuits modulating the LED light source;
one or more detectors; and
one or more readout circuits reading values of the detector;
wherein the LED light source and the detector are positioned such that light output from the LED light source is guided through at least one of the one or more optical waveguides and reaches the detector.

2. The optical interconnect of claim 1, wherein the one or more trenches are two trenches, and wherein the one or more waveguides include at least one optical waveguide layer on the optical substrate between the two trenches.

3. The optical interconnect of claim 2, wherein each of the one or more waveguides is between two cladding layers having different dielectric constants than the one or more waveguides.

4. The optical interconnect of claim 3, further comprising an optical mirror within each trench.

5. The optical interconnect of claim 4, further comprising an electronic substrate wherein at least one of the one or more LED light sources is assembled on the electronic substrate and directed at one trench.

6. The optical interconnect of claim 5, wherein the one or more detectors are assembled on the electronic substrate and positioned to receive light reflected from one of the trenches.

7. The optical interconnect of claim 5, wherein a second of the LED light sources is assembled on the electronic substrate and directed at the other trench, and wherein the one or more detectors are fabricated over or on the same plane as one of the one or more waveguides.

8. The optical interconnect of claim 7, further comprising an optical element integrated on the LED light sources in a wafer-level or die-level assembly.

9. The optical interconnect of claim 5, further comprising an optics assembled on each of the LED light sources modifying optical emission of the LED light sources.

10. The optical interconnect of claim 9, further comprising an optical element assembled on at least one of the one or more detectors.

11. The optical interconnect of claim 5, wherein the one or more detectors are assembled on the electronic substrate and further comprising a wafer-level optical assembly on the one or more LED light sources and the one or more detectors.

12. The optical interconnect of claim 5, wherein one or more additional LED light sources are assembled on the electronic substrate such that light emitted from each LED light source is directed through one of the one or more waveguides to reach one of the one or more detectors and each of the one or more detectors receives light from a different LED light source.

13. The optical interconnect of claim 1, further comprising an optical mirror within one or the one or more trenches positioned to reflect light into one or more of the one or more waveguides; and wherein at least one of the one or more detectors is on the same plane as one of the one or more waveguides.

14. The optical interconnect of claim 13, wherein at least one of the one or more LED light sources is integrated onto the optical substrate.

15. The optical interconnect of claim 14, further comprising an optical element installed on the at least one LED integrated onto the optical substrate.

16. The optical interconnect of claim 15, further comprising:
one or more bonding pads on opposite ends of the optical substrate, the bonding pads acting as connections to one or more other integrated circuits; and
one or more die-to-die adapters, each of the one or more die-to-die adapters implemented in the optical substrate connected to one of the bonding pads.

17. The optical interconnect of claim 13, further comprising a second optical mirror within a second of the one or more trenches positioned to reflect light from a second LED light source into one or more of the one or more waveguides; and a second detector of the one more detectors, and wherein the second detector is on the same plane as one of the one or more waveguides.

18. The optical interconnect of claim 1, wherein the one or more trenches is a single trench etched into the optical substrate, and wherein the one or more waveguides includes a waveguide within the single trench between opposite angled sidewalls of the trench.

19. The optical interconnect of claim 18, further comprising a reflective coating on the opposite angled sidewalls.

20. The optical interconnect of claim 19, further comprising an electrical substrate onto which the optical substrate is integrated, and one or more bonding pads on opposite ends of the electrical substrate, the bonding pads acting as connections to one or more other integrated circuits.

21. The optical interconnect of claim 20, further comprising one or more die-to-die adapters, each of the one or more die-to-die adapters implemented in the electrical substrate between one of the bonding pads and the optical substrate.

22. The optical interconnect of claim 21, further comprising one or more through substrate vias (TSVs) through each of the one or more bonding pads.
